(19) United States
(12) Patent Application Publication
(10) Pub. No.: US 2023/0275132 A1
(43) Pub. Date: Aug. 31, 2023

(54) SEMICONDUCTOR DEVICE AND MANUFACTURING METHOD OF SEMICONDUCTOR DEVICE

(71) Applicant: RENESAS ELECTRONICS CORPORATION, Tokyo (JP)

(72) Inventors: Toshiaki IGARASHI, Tokyo (JP); Sho NAKANISHI, Tokyo (JP); Tomoaki UNO, Tokyo (JP); Koshiro YANAI, Tokyo (JP); Masanari MURAYAMA, Tokyo (JP)

(21) Appl. No.: 18/062,827

(22) Filed: Dec. 7, 2022

(30) Foreign Application Priority Data
Feb. 28, 2022 (JP) 2022-029196

(51) Int. Cl. H01L 29/40; H01L 29/06; H01L 29/739; H01L 29/66

(52) U.S. Cl. CPC H01L 29/404; H01L 29/0623; H01L 29/7397; H01L 29/401; H01L 29/66348

(57) ABSTRACT

An insulating film is formed on a main surface of a semiconductor substrate constituting a semiconductor device so as to cover a field plate portion, a metal pattern thicker than the field plate portion is formed on the insulating film, and a protective film is formed on the insulating film so as to cover the metal pattern. The field plate portion is made of polycrystalline silicon, and the insulating film is composed of a stacked film of one or more silicon nitride films and one or more silicon oxide films.

### CROSS-REFERENCE TO RELATED APPLICATIONS

The disclosure of Japanese Patent Application No. 2022-029196 filed on Feb. 28, 2022 including the specification, drawings and abstract is incorporated herein by reference in its entirety.

### BACKGROUND

The present invention relates to a semiconductor device and a manufacturing method of a semiconductor device, and can be suitably used for, for example, a semiconductor device having a field plate portion and a manufacturing method thereof.

There are disclosed techniques listed below.
[Patent Document 1] Japanese Unexamined Patent Application Publication No. 2019-62031
[Patent Document 2] International Patent Publication No. WO 2013/069408
[Patent Document 3] Japanese Unexamined Patent Application Publication No. 2015-230965

Japanese Unexamined Patent Application Publication No. 2019-62031 (Patent Document 1) and International Patent Publication No. WO 2013/069408 (Patent Document 2) describe techniques related to a semiconductor device having a resistive field plate portion. Also, Japanese Unexamined Patent Application Publication No. 2015-230965 (Patent Document 3) describes a technique related to a metal wiring for suppressing electric field concentration.

### SUMMARY

It is desired to improve the reliability of a semiconductor device having a field plate portion.

The other problems and novel features will be apparent from the description of this specification and the accompanying drawings.

According to an embodiment, a semiconductor device includes: a semiconductor substrate; a field plate portion formed on a main surface of the semiconductor substrate via a first insulating film; and a second insulating film formed on the main surface of the semiconductor substrate so as to cover the first insulating film and the field plate portion. The semiconductor device further includes: a first metal pattern and a second metal pattern formed on the second insulating film; and an insulating protective film formed on the second insulating film so as to cover the first metal pattern and the second metal pattern. Each of the first metal pattern and the second metal pattern is electrically connected to the field plate portion and is thicker than the field plate portion. The field plate portion is made of polycrystalline silicon, and the second insulating film is composed of a stacked film of one or more silicon nitride films and one or more silicon oxide films.

According to the embodiment, it is possible to improve the reliability of the semiconductor device.

### BRIEF DESCRIPTION OF THE DRAWINGS

FIG. 1 is a top view of a semiconductor device according to the embodiment.

FIG. 2 is a bottom view of the semiconductor device according to the embodiment.

FIG. 3 is a plan perspective view of the semiconductor device according to the embodiment.

FIG. 4 is a plan view showing the principal part of the semiconductor device according to the embodiment.

FIG. 5 is a plan perspective view of the semiconductor device according to the embodiment.

FIG. 6 is a cross-sectional view showing the principal part of the semiconductor device according to the embodiment.

FIG. 7 is a cross-sectional view showing the principal part of the semiconductor device according to the embodiment.

FIG. 8 is a cross-sectional view showing the principal part of the semiconductor device according to the embodiment.

FIG. 9 is a cross-sectional view showing the principal part in a manufacturing process of the semiconductor device according to the embodiment.

FIG. 10 is a cross-sectional view showing the principal part in the manufacturing process of the semiconductor device subsequent to FIG. 9.

FIG. 11 is a cross-sectional view showing the principal part in the manufacturing process of the semiconductor device subsequent to FIG. 10.

FIG. 12 is a cross-sectional view showing the principal part in the manufacturing process of the semiconductor device subsequent to FIG. 11.

FIG. 13 is a cross-sectional view showing the principal part in the manufacturing process of the semiconductor device subsequent to FIG. 12.

FIG. 14 is a cross-sectional view showing the principal part in the manufacturing process of the semiconductor device subsequent to FIG. 13.

FIG. 15 is a cross-sectional view showing the principal part in the manufacturing process of the semiconductor device subsequent to FIG. 14.

FIG. 16 is a cross-sectional view showing the principal part in the manufacturing process of the semiconductor device subsequent to FIG. 15.

FIG. 17 is a cross-sectional view showing the principal part in the manufacturing process of the semiconductor device subsequent to FIG. 16.

FIG. 18 is a cross-sectional view showing the principal part in the manufacturing process of the semiconductor device subsequent to FIG. 17.

FIG. 19 is a cross-sectional view showing the principal part in the manufacturing process of the semiconductor device subsequent to FIG. 18.

FIG. 20 is a cross-sectional view showing the principal part of a semiconductor device according to the first studied example.

FIG. 21 is a cross-sectional view showing the principal part of a semiconductor device according to the second studied example.

FIG. 22 is a cross-sectional view showing the principal part of a semiconductor device according to the third studied example.

FIG. 23 is a cross-sectional view showing the principal part of a semiconductor device according to the first modification.

FIG. 24 is a cross-sectional view showing the principal part of a semiconductor device according to the second modification.

FIG. 25 is a cross-sectional view showing the principal part of a semiconductor device according to the third modification.

### DETAILED DESCRIPTION

In the following description, the invention will be described in a plurality of sections or embodiments when required as a matter of convenience. However, these sections or embodiments are not irrelevant to each other unless otherwise stated, and the one relates to the entire or a part of the other as a modification, details, or a supplementary explanation thereof. Also, in the embodiments described below, when mentioning the number of elements (including number of pieces, values, amount, range, and the like), the number of the elements is not limited to a specific number unless otherwise stated or except the case where the number is apparently limited to a specific number in principle, and the number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, an embodiment will be described in detail with reference to drawings. In all the drawings for describing the embodiment, the members having the same function are denoted by the same reference characters and the repetitive description thereof will be omitted. Also, in the following embodiment, the description of the same or similar components is not repeated in principle unless particularly required.

Also, in some drawings used in the following embodiment, hatching is omitted even in a cross-sectional view so as to make the drawings easy to see. In addition, hatching is used even in a plan view so as to make the drawings easy to see.

### First Embodiment

<Structure of Semiconductor Device>

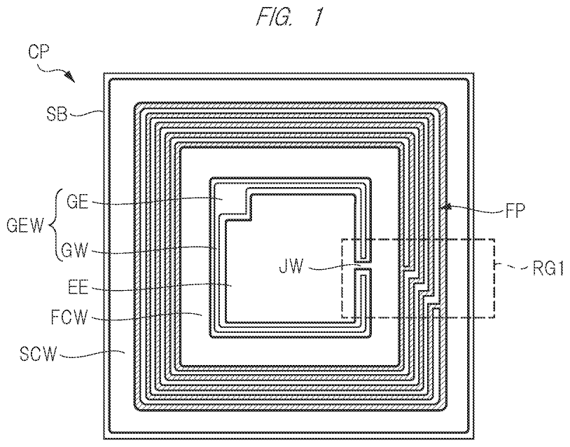

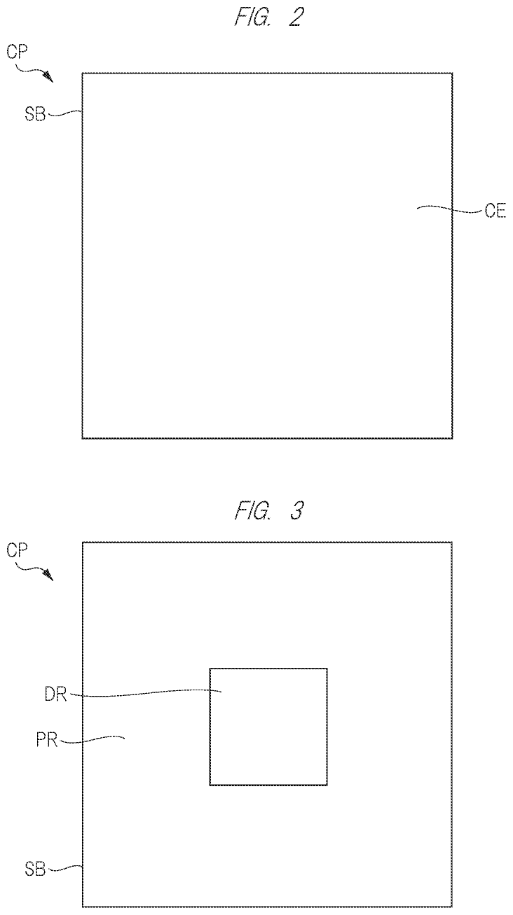

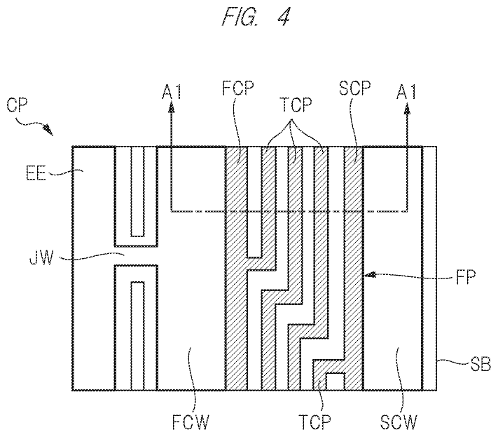

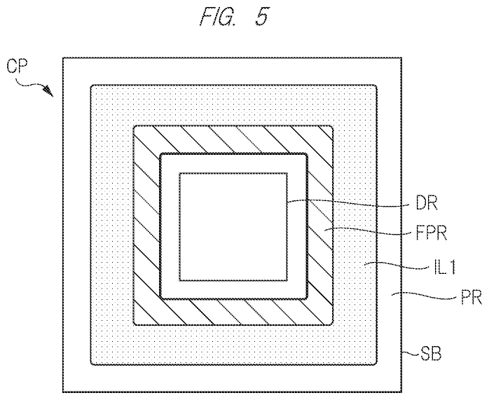

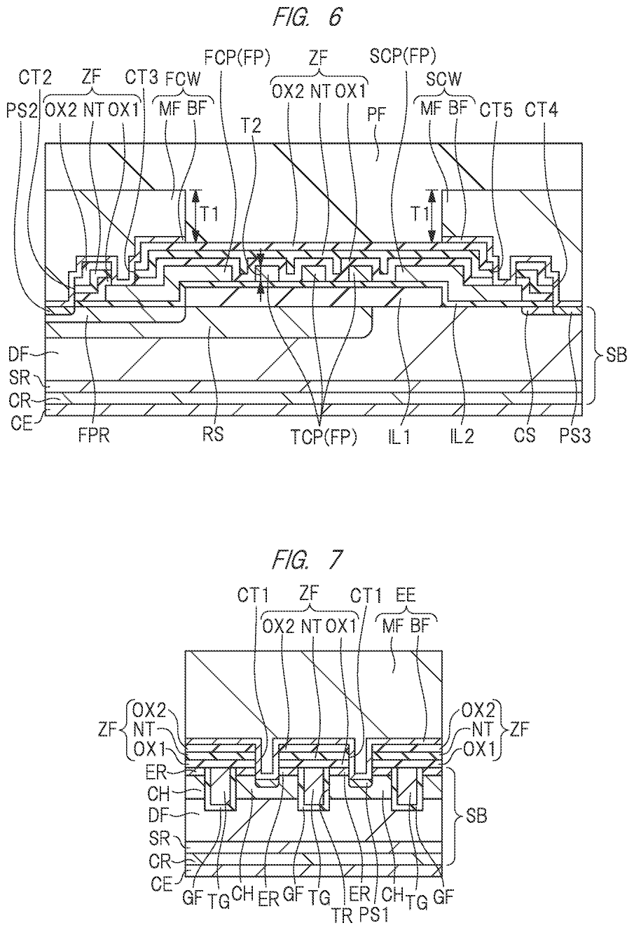

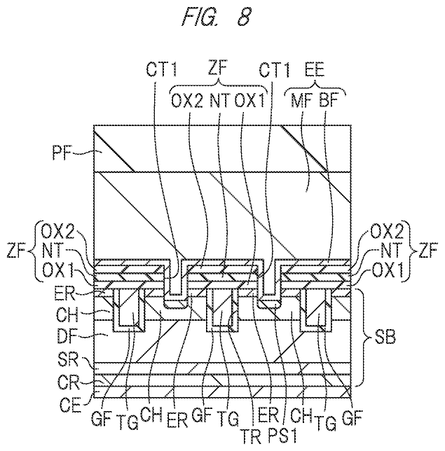

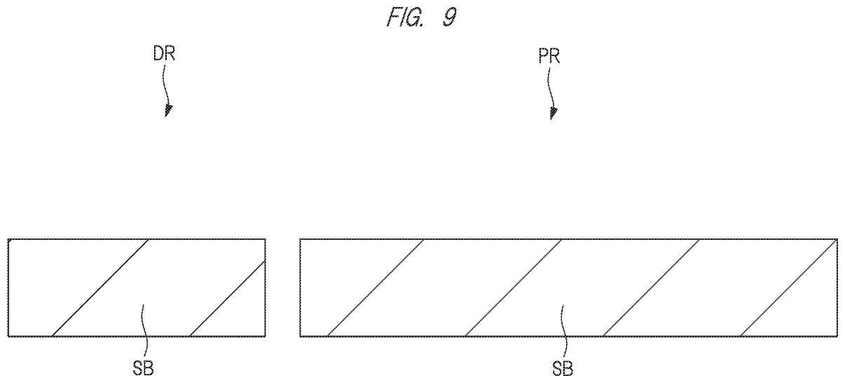

A structure of a semiconductor device CP according to the present embodiment will be described with reference to FIG. 1 to FIG. 9. FIG. 1 is a top view of the semiconductor device CP according to the present embodiment and FIG. 2 is a bottom view (back side view) of the semiconductor device CP according to the present embodiment. FIG. 3 is a plan perspective view of the semiconductor device CP according to the present embodiment and FIG. 4 is a plan view showing the principal part of the semiconductor device CP according to the present embodiment. FIG. 5 is a plan perspective view of the semiconductor device CP according to the present embodiment, and it shows formation positions of a p-type semiconductor region FPR and an insulating film IL1 with hatching. FIG. 6 to FIG. 8 are cross-sectional views each showing the principal part of the semiconductor device CP according to the present embodiment. A partially enlarged plan view showing a region RG1 surrounded by a dotted line in FIG. 1 in an enlarged manner corresponds to FIG. 4. Also, a cross-sectional view taken along the line A1-A1 in FIG. 4 corresponds to FIG. 6. Further, FIG. 7 and FIG. 8 are cross-sectional views each showing the principal part of an element region DR shown in FIG. 3. Specifically, FIG. 7 corresponds to a cross-sectional view in a region where an emitter electrode EE is exposed from an opening (opening for emitter pad) of a protective film PF and FIG. 8 corresponds to a cross-sectional view in a region where the emitter electrode EE is covered with the protective film PF.

The semiconductor device (semiconductor chip) CP according to the present embodiment is, for example, a power device including a power transistor (power system transistor), and the power transistor is formed on a semiconductor substrate SB constituting the semiconductor device CP. The semiconductor substrate SB constituting the semiconductor device CP is made of, for example, single crystal silicon, and has a main surface and a back surface opposite to the main surface. The semiconductor device CP and the semiconductor substrate SB constituting it have a rectangular planar shape.

The semiconductor device CP includes, as an uppermost layer wiring, an emitter electrode EE, a gate electrode wiring GEW, an inner circumferential wiring (metal pattern) FCW, an outer circumferential wiring (metal pattern) SCW, and a connection wiring portion JW. Since the emitter electrode EE, the gate electrode wiring GEW, the inner circumferential wiring FCW, and the outer circumferential wiring SCW are each made of a metal material, they can be regarded as metal electrodes, metal wirings or metal patterns. The emitter electrode EE, the gate electrode wiring GEW, the inner circumferential wiring FCW, and the outer circumferential wiring SCW are wirings (metal patterns) in the same layer, and are composed of a stacked conductor film of a barrier conductor film BR and a main conductor film MC formed thereon.

In plan view, the emitter electrode EE is arranged at the center of the semiconductor device CP, the gate electrode wiring GEW is arranged around (outside) the emitter electrode EE, the inner circumferential wiring FCW is arranged around (outside) the gate electrode wiring GEW, and the outer circumferential wiring SCW is arranged around (outside) the inner circumferential wiring FCW.

In this application, the phrase “in plan view” corresponds to the case of viewing on a plane parallel to a main surface or a back surface of the semiconductor device CP or the semiconductor substrate SB.

The emitter electrode EE is electrically connected to an emitter region of the power transistor formed in the semiconductor device CP (semiconductor substrate SB). For example, the emitter electrode EE is formed in a substantially square shape in plan view.

The gate electrode wiring GEW is electrically connected to a gate electrode of the power transistor formed in the semiconductor device CP (semiconductor substrate SB). The gate electrode wiring GEW is arranged around the emitter electrode EE so as to surround the emitter electrode EE in plan view, and includes a gate electrode portion GE and a gate wiring portion GW formed integrally. For example, the gate electrode portion GE is formed in a substantially square shape in plan view, and is arranged near one corner of the emitter electrode EE. Further, the gate wiring portion GW is formed of a band-like pattern narrower than the gate electrode portion GE, and is arranged so as to surround the emitter electrode EE in plan view.

The inner circumferential wiring FCW is arranged around the gate electrode wiring GEW so as to surround the gate electrode wiring GEW in plan view. The inner circumferential wiring FCW is electrically connected to the emitter electrode EE through the connection wiring portion JW. The inner circumferential wiring FCW, the connection wiring portion JW, and the emitter electrode EE are made of the same conductor film and are integrally formed.

The outer circumferential wiring SCW is arranged around the inner circumferential wiring FCW so as to surround the inner circumferential wiring FCW in plan view. The outer circumferential wiring SCW is electrically connected to a collector region of the power transistor formed in the semiconductor device CP (semiconductor substrate SB).

The semiconductor device CP further includes a field plate portion (resistive field plate portion, conductive plate portion) FP that electrically connects the inner circumferential wiring FCW and the outer circumferential wiring SCW. The field plate portion FP is a resistive field plate portion made of polycrystalline silicon. The field plate portion FP is arranged between the inner circumferential wiring FCW and the outer circumferential wiring SCW in plan view. Although FIG. 1 and FIG. 4 are plan views, hatching is applied to the field plate portion FP so as to make the drawing easier to see. The field plate portion FP is formed of conductor patterns FCP, TCP, and SCP that electrically connect a collector and an emitter of the power transistor.

As can be seen from FIG. 3, the element region (active region, inner peripheral region) DR is arranged at the center of the main surface of the semiconductor substrate SB constituting the semiconductor device CP. Further, on the main surface of the semiconductor substrate SB, a peripheral region (outer peripheral region) PR is arranged around the element region DR so as to surround the element region DR.

The element region DR is a region in which a semiconductor element is formed. A plurality (a large number) of unit transistor cells is arranged in the element region DR, and a power transistor is configured by connecting the plurality of unit transistors in parallel. Each unit transistor cell has the same structure.

The unit transistor cell in the element region DR will be described below with reference to FIG. 7 and FIG. 8. FIG. 7 and FIG. 8 are cross-sectional views showing the principal part of an example of the unit transistor cell arranged in the element region DR of FIG. 3. As described above, FIG. 7 corresponds to a cross-sectional view in a region where the emitter electrode EE is exposed from an opening of the protective film PF and FIG. 8 corresponds to a cross-sectional view in a region where the emitter electrode EE is covered with the protective film PF.

As shown in FIG. 7 and FIG. 8, for example, a mesa-type insulated gate bipolar transistor (IGBT) is formed as the unit transistor cell. In the following description, the insulated gate bipolar transistor is simply referred to as a transistor. The transistor (element) includes a p-type collector region CR and an n-type emitter region ER, an n⁻-type drift region DF and a p-type channel formation region CH therebetween, and a trench gate electrode TG.

Namely, on the back surface side of the semiconductor substrate SB, the p-type collector region CR is formed so as to reach a predetermined depth from the back surface of the semiconductor substrate SB. The collector region CR is composed of a p-type semiconductor region formed in the semiconductor substrate SB. A collector electrode CE is formed on the back surface of the semiconductor substrate SB, and the collector region CR is adjacent to and electrically connected to the collector electrode CE. The collector electrode CE is composed of, for example, a stacked film of an aluminum (Al) layer on the back surface of the semiconductor substrate SB, a titanium (Ti) layer on the aluminum layer, a nickel (Ni) layer on the titanium layer, and a gold (Au) layer on the nickel layer. The collector electrode CE is formed over the entire back surface of the semiconductor substrate SB.

An n-type field stop region SR is formed between the p-type collector region CR and the n⁻-type drift region DF. The field stop region SR is composed of an n-type semiconductor region formed in the semiconductor substrate SB, and the drift region DF is composed of an n-type semiconductor region formed in the semiconductor substrate SB. The n-type impurity concentration of the field stop region SR is higher than the n-type impurity concentration of the drift region DF, and the n-type impurity concentration of the emitter region ER is higher than the n-type impurity concentration of the field stop region SR. The field stop region SR has a function of preventing a punch-through phenomenon (a phenomenon in which a depletion layer growing in the drift region DF from the channel formation region CH comes in contact with the collector region CR) from occurring when the transistor is turned off. Also, the field stop region SR has a function of limiting the amount of holes injected from the collector region CR to the drift region DF.

On the main surface side of the semiconductor substrate SB, the n-type emitter region ER is formed so as to reach a predetermined depth from the main surface of the semiconductor substrate SB. The emitter region ER is composed of an n-type semiconductor region formed in the semiconductor substrate SB. As to the drift region DF and the channel formation region CH, the channel formation region CH is adjacent to the emitter region ER, the emitter region ER is located on the channel formation region CH, and the channel formation region CH is interposed between the emitter region ER and the drift region DF. The p-type channel formation region CH is composed of a p-type semiconductor region formed in the semiconductor substrate SB.

Further, in the element region DR, trenches (gate trenches) TR extending from the main surface of the semiconductor substrate SB in the thickness direction thereof are formed in the semiconductor substrate SB. Each trench TR is formed so as to reach the drift region DF through the emitter region ER and the channel formation region CH below the emitter region ER. From another point of view, the channel formation region CH is formed between adjacent trenches TR, and the emitter region ER is formed on the channel formation region CH at a position adjacent to the trench TR.

The trench gate electrode TG is buried in the trench TR via a gate insulating film GF. The gate insulating film GF is composed of, for example, a silicon oxide film and formed on the bottom and side surfaces of the trench TR. The trench gate electrode TG is composed of, for example, a polycrystalline silicon film into which an n-type impurity (for example, phosphorus) is introduced. The trench gate electrode TG functions as a gate (gate electrode) of the unit transistor cell. The trench gate electrode TG is electrically connected to the gate electrode wiring GEW mentioned above.

Also, an insulating film ZF is formed on the main surface of the semiconductor substrate SB so as to cover the upper surfaces of the emitter region ER and the trench gate electrode TG. The insulating film ZF is composed of a stacked film of one or more silicon nitride films and one or more silicon oxide films. In the case of FIG. 7 and FIG. 8, the insulating film ZF is composed of a stacked film of a silicon oxide film OX1, a silicon nitride film NT on the silicon oxide film OX1, and a silicon oxide film OX2 on the silicon nitride film NT. The emitter electrode EE mentioned above is formed on the insulating film ZF.

The emitter electrode EE is composed of a stacked film of a barrier conductor film BF and a main conductor film MF formed thereon. The thickness of the main conductor film MF is larger than the thickness of the barrier conductor film BF. The barrier conductor film BF is made of, for example, titanium tungsten (TiW). The main conductor film MF is composed of, for example, a single film of aluminum (Al), a conductor film in which Si or copper (Cu) is added to Al, or a conductor film in which Si and Cu are added to Al. Among these, AlSi is preferable from the viewpoint of suppressing Al spikes. The content of Si in AlSi is, for example, in the range of 0.5% to 1.5%.

Further, in the element region DR, contact holes (connection trenches) CT1 are formed so as to reach the channel formation region CH through the insulating film ZF and the emitter region ER. Each contact hole CT1 is filled with the emitter electrode EE. The emitter electrode EE is in contact with and electrically connected to the emitter region ER exposed from the side surface of the contact hole CT1. Also, the emitter electrode EE is electrically connected to the p-type channel formation region CH through a p⁺-type semiconductor region PS1 formed in the semiconductor substrate SB at a position adjacent to the bottom of the contact hole CT1. In plan view, the emitter electrode EE is formed over the entire element region DR in which a plurality of unit transistor cells constituting the power transistor is formed.

The semiconductor device CP includes an insulating protective film (surface protective film, passivation film) PF as a film (insulating film) of the uppermost layer. The protective film PF is composed of an insulating film, preferably a resin film made of polyimide resin or the like. In the present embodiment, the protective film PF does not include a silicon nitride film. The emitter electrode EE, the gate electrode wiring GEW, the inner circumferential wiring FCW, the outer circumferential wiring SCW, and the connection wiring portion JW are covered with the protective film PF. Namely, the protective film PF is formed on the insulating film ZF so as to cover the emitter electrode EE, the gate electrode wiring GEW, the inner circumferential wiring FCW, the outer circumferential wiring SCW, and the connection wiring portion JW. The protective film PF is in contact with the emitter electrode EE, the gate electrode wiring GEW, the inner circumferential wiring FCW, and the outer circumferential wiring SCW.

However, the opening for a pad (bonding pad) is formed in the protective film PF. The opening for emitter pad in the protective film PF is formed so as to be included in the emitter electrode EE in plan view, and a part of the emitter electrode EE is exposed from the opening for emitter pad in the protective film PF. The emitter pad (bonding pad for emitter) is formed of the emitter electrode EE exposed from the opening for emitter pad in the protective film PF. In addition, the opening for gate pad in the protective film PF is formed so as to be included in the gate electrode portion GE in plan view, and a part of the gate electrode portion GE is exposed from the opening for gate pad in the protective film PF. The gate pad (bonding pad for gate) is formed of the gate electrode portion GE exposed from the opening for gate pad in the protective film PF. The gate wiring portion GW, the inner circumferential wiring FCW, the outer circumferential wiring SCW, and the connection wiring portion JW are entirely covered with the protective film PF and are not exposed from the protective film PF.

The trench gate electrodes TG of the plurality of unit transistor cells formed in the element region DR are electrically connected to each other through the gate electrode wiring GEW. Therefore, a gate voltage is supplied from the gate pad to the gate of the power transistor (trench gate electrodes TG of the plurality of unit transistor cells constituting the power transistor) through the gate electrode wiring GEW.

Also, the emitter regions ER of the plurality of unit transistor cells constituting the power transistor are electrically connected to the emitter electrode EE, and are electrically connected to each other through the emitter electrode EE.

Further, the collector regions of the plurality of unit transistor cells constituting the power transistor are electrically connected to each other through the collector region CR and the collector electrode CE.

Here, the case where the IGBT is applied as a semiconductor element formed in the element region DR has been described. As another aspect, a power MOSFET may be formed instead of the above-described IGBT as the semiconductor element formed in the element region DR. In that case, the emitter region ER becomes the source region, the emitter electrode EE becomes the source electrode, the collector region CR is not formed, and the collector electrode CE becomes the drain electrode. Also, as the semiconductor element formed in the element region DR, other transistors such as RC (Reverse-Conducting)-IGBT, bipolar transistor, etc. may be applied as the unit transistor cell instead of the IGBT and power MOSFET. Further, a diode can also be applied as the semiconductor element formed in the element region DR. In that case, one of the emitter electrode EE and the collector electrode CE becomes the anode electrode, the other becomes the cathode electrode, and the gate electrode wiring GEW is not formed.

Next, the peripheral region (PR) of the semiconductor device CP (semiconductor substrate SB) will be described with reference to FIG. 1 and FIG. 4 to FIG. 6.

As shown in FIG. 6, in the peripheral region of the semiconductor device CP, the p-type semiconductor region FPR and a p⁻-type RESURF (REduced SURface Field) region RS are formed on the main surface side of the semiconductor substrate SB. The p-type semiconductor region FPR is composed of a p-type semiconductor region formed in the semiconductor substrate SB, the RESURF region RS is composed of a p⁻-type semiconductor region formed in the semiconductor substrate SB, and the impurity concentration of the p⁻-type RESURF region RS (p-type impurity concentration) is lower than the impurity concentration (p-type impurity concentration) of the p-type semiconductor region FPR. As shown in FIG. 5, the planar shape of the p-type semiconductor region FPR is formed in a frame shape in plan view so as to surround the element region DR. The p-type semiconductor region FPR is fixed at a potential of 0 V (ground potential) when the power transistor is turned off.

The p⁻-type RESURF region RS is also formed so as to surround the element region DR. The RESURF region RS extends toward the outer periphery of the semiconductor device CP in the state of being electrically connected to the p-type semiconductor region FPR, and is formed below (immediately below) the field plate portion FP. The combination of the field plate portion FP and the RESURF region RS is very compatible with each other in terms of withstand voltage characteristics, and the electric field (surface field) of the main surface of the semiconductor substrate SB can be relaxed and the withstand voltage can be improved by providing the RESURF region RS.

Further, on the main surface of the semiconductor substrate SB, an n⁺-type channel stopper region CS is formed further outside (on the outer peripheral side of) the field plate portion FP so as to surround the field plate portion FP. The channel stopper region CS has a function of suppressing the extension of the depletion layer extending from the p-type semiconductor region FPR. The channel stopper region CS is fixed at a potential of, for example, about 600 V when the power transistor is turned off.

Further, as shown in FIG. 6, in the peripheral region of the semiconductor device CP, the insulating film IL1 and an insulating film IL2 that covers the insulating film IL1 are formed on the main surface of the semiconductor substrate SB. The thickness of the insulating film IL1 is larger than the thickness of the insulating film IL2. The insulating film IL1 is composed of, for example, a silicon oxide film, and the thickness of the insulating film IL1 is, for example, about 1 μm. As shown in FIG. 5, the planar shape of the insulating film IL1 is formed in a frame shape in plan view so as to surround the p-type semiconductor region FPR. The p-type semiconductor region FPR is formed in a self-aligned manner with respect to the insulating film IL1, and the outer peripheral edge of the p-type semiconductor region FPR substantially coincides with the inner peripheral edge of the thick insulating film IL1 in plan view. The insulating film IL2 is composed of, for example, a silicon oxide film like the insulating film IL1, but is thinner than the insulating film IL1, and the thickness of the insulating film IL2 is, for example, about 0.2 μm.

Further, as shown in FIG. 6, the above-described field plate portion FP is formed on the insulating film IL1 and the insulating film IL2. The field plate portion FP is a structure for ensuring the withstand voltage of the peripheral region PR of the semiconductor device CP when the power transistor is turned off. The field plate portion FP is arranged in the peripheral region PR of the semiconductor device CP (see FIG. 3) in the state of being electrically connected between the collector and the emitter of the power transistor (the power transistor configured by a plurality of unit transistor cells formed in the element region DR). By passing a current through the conductor patterns FCP, TCP, and SCP constituting the field plate portion FP, a field plate having a constant potential can be formed, and the withstand voltage of the peripheral region can be ensured by the potential distribution thereof.

As shown in FIG. 1, FIG. 4, and FIG. 6, the field plate portion FP integrally includes the inner conductor pattern FCP, the outer conductor pattern SCP, and the intermediate conductor pattern TCP for electrically connecting these patterns (conductor pattern FCP and conductor pattern SCP). These conductor patterns FCP, SCP, and TCP are made of polycrystalline silicon (polysilicon) and have a thickness of, for example, about 500 to 600 nm. The conductor patterns FCP, SCP, and TCP contain impurities (n-type or p-type impurities) at a predetermined concentration so as to have a resistivity suitable for the field plate. The impurity concentration of the conductor patterns FCP, SCP, and TCP can be, for example, about 1×10¹⁷/cm³ to 1×10²⁰/cm³.

As can be seen from FIG. 1 and FIG. 4, the inner conductor pattern FCP is formed in a frame shape so as to surround the element region DR in plan view. As shown in FIG. 6, the inner conductor pattern FCP integrally has a portion overlapping the insulating film IL1 and a portion not overlapping the insulating film IL1 in plan view. Namely, the portion of the inner conductor pattern FCP on the inner peripheral side is formed on the insulating film IL2 on the semiconductor substrate SB (p-type semiconductor region FPR), and the insulating film IL1 does not exist therebelow. However, the portion of the inner conductor pattern FCP on the outer peripheral side is formed on the insulating film IL2 on the insulating film IL1, and the insulating film IL1 exists therebelow.

As can be seen from FIG. 1 and FIG. 4, the outer conductor pattern SCP is formed in a frame shape so as to surround the inner conductor pattern FCP in plan view. As shown in FIG. 6, the outer conductor pattern SCP integrally has a portion overlapping the insulating film IL1 and a portion not overlapping the insulating film IL1 in plan view. Namely, the portion of the outer conductor pattern SCP on the inner peripheral side is formed on the insulating film IL2 on the insulating film IL1, and the insulating film IL1 exists therebelow. However, the portion of the outer conductor pattern SCP on the outer peripheral side is formed on the insulating film IL2 on the semiconductor substrate SB, and the insulating film IL1 does not exist therebelow.

As can be seen from FIG. 1 and FIG. 4, the intermediate conductor pattern TCP is formed between the inner conductor pattern FCP and the outer conductor pattern SCP in plan view, and is formed on the insulating film IL2 on the insulating film IL1 in cross-sectional view. Therefore, the insulating film IL1 exists below the intermediate conductor pattern TCP.

Further, as shown in FIG. 1 and FIG. 4, the intermediate conductor pattern TCP is formed in, for example, a spiral shape (vortex shape) in plan view. Of both ends of the intermediate conductor pattern TCP located on opposite sides, one end is integrally connected to the inner conductor pattern FCP, and the other end is integrally connected to the outer conductor pattern SCP.

By passing a current (for example, a current of about several μA) through the conductor patterns FCP, TCP, and SCP of the field plate portion FP from the collector to the emitter (that is, from the outer conductor pattern SCP to the inner conductor pattern FCP), the potential is divided by the conductor patterns FCP, TCP, and SCP, and a field plate having a constant potential is formed in the peripheral region PR. Then, the electric field distribution inside the semiconductor substrate SB in the peripheral region PR is made uniform by the potential distribution of the field plate, and the potential on the upper surface of the semiconductor substrate SB is fixed, with the result that the withstand voltage of the peripheral region PR of the semiconductor device CP is improved and the reliability of the semiconductor device CP is improved. In addition, in the peripheral structure using the field plate portion FP, the potential distribution between the collector and the emitter is fixed by the current flowing through the conductor patterns FCP, SCP, and TCP, so that the semiconductor device CP is less likely to be affected by external charges.

As shown in FIG. 6, the insulating film ZF described above is formed on the main surface of the semiconductor substrate SB so as to cover the field plate portion FP (conductor patterns FCP, SCP, and TCP), the insulating film IL2, and the like. Further, the above-described inner circumferential wiring FCW and outer circumferential wiring SCW are formed on the insulating film ZF. The inner circumferential wiring FCW and the outer circumferential wiring SCW are composed of a stacked film of the barrier conductor film BF and the main conductor film MF formed thereon like the emitter electrode EE.

As shown in FIG. 6, the inner circumferential wiring FCW is electrically connected to the p-type semiconductor region FPR through a contact hole CT2 formed in the insulating film ZF and the insulating film IL2. Namely, the contact hole CT2 is formed at a position overlapping the p-type semiconductor region FPR in plan view, penetrates through the insulating film ZF and the insulating film IL2 below the insulating film ZF, and is filled with the inner circumferential wiring FCW. The inner circumferential wiring FCW is electrically connected to a portion of the semiconductor substrate SB exposed from (the contact hole CT of) the insulating film ZF. Specifically, the p-type semiconductor region FPR is exposed at the bottom of the contact hole CT2, and the inner circumferential wiring FCW in the contact hole CT2 and the p-type semiconductor region FPR are electrically connected. Also, at the position adjacent to the bottom of the contact hole CT2 in the p-type semiconductor region FPR, a p⁺-type semiconductor region PS2 having an impurity concentration higher than that of the p-type semiconductor region FPR is formed, whereby the inner circumferential wiring FCW can be electrically connected to the p-type semiconductor region FPR through p⁺-type semiconductor region PS2. In this way, the connection resistance between the inner circumferential wiring FCW and the p-type semiconductor region FPR can be reduced.

Further, as shown in FIG. 6, the inner circumferential wiring FCW is electrically connected to the conductor pattern FCP of the field plate portion FP through a contact hole CT3 formed in the insulating film ZF. Namely, the contact hole CT3 is formed at a position overlapping the conductor pattern FCP of the field plate portion FP in plan view, penetrates through the insulating film ZF, and is filled with the inner circumferential wiring FCW. The conductor pattern FCP of the field plate portion FP is exposed at the bottom of the contact hole CT3, and the inner circumferential wiring FCW in the contact hole CT3 and the conductor pattern FCP of the field plate portion FP are electrically connected. Also, at the position adjacent to the bottom of the contact hole CT3 in the conductor pattern FCP of the field plate portion FP, a p⁺-type semiconductor region (not shown) having an impurity concentration higher than that of the conductor pattern FCP is formed, whereby the inner circumferential wiring FCW can be electrically connected to the conductor pattern FCP of the field plate portion FP through the p⁺-type semiconductor region. In this way, the connection resistance between the inner circumferential wiring FCW and the conductor pattern FCP of the field plate portion FP can be reduced. In the case of FIG. 6, the contact hole CT3 is formed on the portion of the conductor pattern FCP that is not located on the insulating film IL1 instead of on the portion of the conductor pattern FCP that is located on the insulating film IL1.

As another aspect, it is also possible to provide the contact hole CT3 on the portion of the conductor pattern FCP that is located on the insulating film IL1 (that is, on the conductor pattern FCP at the position overlapping the insulating film IL1 in plan view). Further, in that case, the entire conductor pattern FCP may overlap the insulating film IL1 in plan view.

The contact hole CT3 can be formed so as to extend along the outer periphery of the inner circumferential wiring FCW in plan view, and the same applies to the contact hole CT2.

Further, as shown in FIG. 6, the outer circumferential wiring SCW is electrically connected to a p⁺-type semiconductor region PS3 and the n⁺-type channel stopper region CS through a contact hole CT4 formed in the insulating film ZF and the insulating film IL2. The p⁺-type semiconductor region PS3 is a p-type semiconductor region formed in the semiconductor substrate SB, and the channel stopper region CS is an n-type semiconductor region formed in the semiconductor substrate SB. The contact hole CT4 is formed at a position overlapping the p⁺-type semiconductor region PS3 in plan view, penetrates through the insulating film ZF and the insulating film IL2 below the insulating film ZF, and is filled with the outer circumferential wiring SCW. The outer circumferential wiring SCW is electrically connected to a portion of the semiconductor substrate SB exposed from (the contact hole CT4 of) the insulating film ZF. Specifically, the outer circumferential wiring SCW in the contact hole CT4 is electrically connected to the p⁺-type semiconductor region PS3 exposed at the bottom of the contact hole CT2. The outer circumferential wiring SCW is electrically connected to the collector region CR on the back surface side of the semiconductor substrate SB through the contact hole CT4 and the p⁺-type semiconductor region PS3. Therefore, the outer circumferential wiring SCW is electrically connected to the collector electrode CE through the semiconductor substrate SB.

Further, as shown in FIG. 6, the outer circumferential wiring SCW is electrically connected to the conductor pattern SCP of the field plate portion FP through a contact hole CT5 formed in the insulating film ZF. Namely, the contact hole CT5 is formed at a position overlapping the conductor pattern SCP of the field plate portion FP in plan view, penetrates through the insulating film ZF, and is filled with the outer circumferential wiring SCW. The conductor pattern SCP of the field plate portion FP is exposed at the bottom of the contact hole CT5, and the outer circumferential wiring SCW in the contact hole CT5 and the conductor pattern SCP of the field plate portion FP are electrically connected. Also, at the position adjacent to the bottom of the contact hole CT5 in the conductor pattern SCP of the field plate portion FP, a p⁺-type semiconductor region (not shown) having an impurity concentration higher than that of the conductor pattern SCP is formed, whereby the outer circumferential wiring SCW can be electrically connected to the conductor pattern SCP of the field plate portion FP through the p⁺-type semiconductor region. In this way, the connection resistance between the outer circumferential wiring SCW and the conductor pattern SCP of the field plate portion FP can be reduced. In the case of FIG. 6, the contact hole CT5 is formed on the portion of the conductor pattern SCP that is not located on the insulating film IL1 instead of on the portion of the conductor pattern SCP that is located on the insulating film IL1.

As another aspect, it is also possible to provide the contact hole CT5 on the portion of the conductor pattern SCP that is located on the insulating film IL1 (that is, on the conductor pattern SCP at the position overlapping the insulating film IL1 in plan view). Further, in that case, the entire conductor pattern SCP may overlap the insulating film IL1 in plan view.

The contact hole CT5 can be formed so as to extend along the outer periphery of the outer circumferential wiring SCW in plan view, and the same applies to the contact hole CT4.

Therefore, in the element region DR of the semiconductor device CP (semiconductor substrate SB), the insulating film ZF is formed on the main surface of the semiconductor substrate SB so as to cover the emitter region ER and the trench gate electrode TG. Also, in the peripheral region PR of the semiconductor device CP (semiconductor substrate SB), the field plate portion FP is formed on the main surface of the semiconductor substrate SB via an insulating film (here, an insulating film composed of the insulating film IL1 and the insulating film IL2). Further, the insulating film ZF is formed on the main surface of the semiconductor substrate SB so as to cover the insulating films IL1 and IL2 and the field plate portion FP (conductor patterns FCP, SCP, and TCP). The insulating film ZF can function as an interlayer insulating film, and it can function also as a protective film for the field plate portion FP because it covers the field plate portion FP. Furthermore, the emitter electrode EE, the gate electrode wiring GEW, the inner circumferential wiring FCW, and the outer circumferential wiring SCW are formed on the insulating film ZF, and the protective film PF is formed on the insulating film ZF so as to cover them.

The thickness of each of the emitter electrode EE, the gate electrode wiring GEW, the inner circumferential wiring FCW, and the outer circumferential wiring SCW is larger than the thickness of the field plate portion FP (conductor patterns FCP, SCP, and TCP). Note that the thickness of each of the emitter electrode EE, the gate electrode wiring GEW, the inner circumferential wiring FCW, and the outer circumferential wiring SCW can be defined as the thickness of the portion located on the insulating film ZF (thickness T1 shown in FIG. 6). FIG. 6 also shows the thickness T2 of the field plate portion FP, and T1>T2 holds.

The protective film PF is the film in the uppermost layer of the semiconductor device CP, which is a semiconductor chip. A part (central part) of the emitter electrode EE is exposed from the opening of the protective film PF to form the emitter pad, and a part of the gate electrode portion GE of the gate electrode wiring GEW is exposed from the opening of the protective film PF to form the gate pad.

<Manufacturing Method of Semiconductor Device>

Next, an example of a manufacturing method of the semiconductor device according to the present embodiment will be described with reference to FIG. 9 to FIG. 19. FIGS. 9 to 19 are cross-sectional views each showing the principal part in the manufacturing process of the semiconductor device according to the present embodiment. In each of FIG. 9 to FIG. 19, the cross-section shown on the left side in the drawing is the cross-section corresponding to FIG. 7 above, and the cross-section shown on the right side in the drawing is the cross-section corresponding to FIG. 6 above.

First, as shown in FIG. 9, the semiconductor substrate SB is prepared. At this stage, the semiconductor substrate SB is a substantially circular semiconductor wafer in plan view. The semiconductor substrate SB has a main surface and a back surface on the opposite side thereto. The semiconductor substrate SB is made of, for example, single crystal silicon, and can be an n⁻-type semiconductor substrate into which an n-type impurity is introduced. An epitaxial wafer in which an epitaxial semiconductor layer is formed on a semiconductor substrate can also be used as the semiconductor substrate SB.

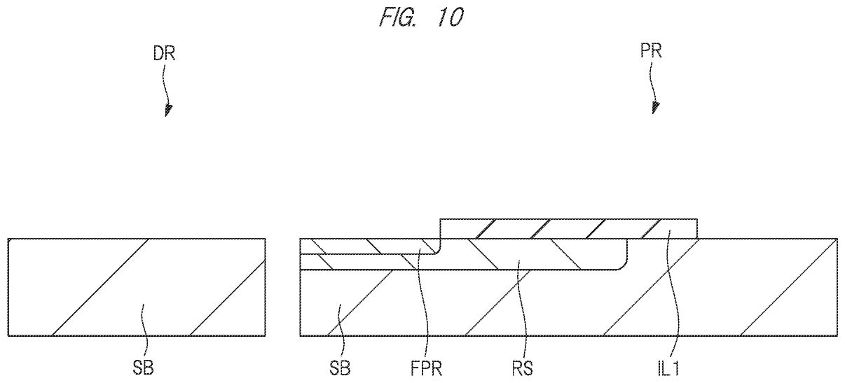

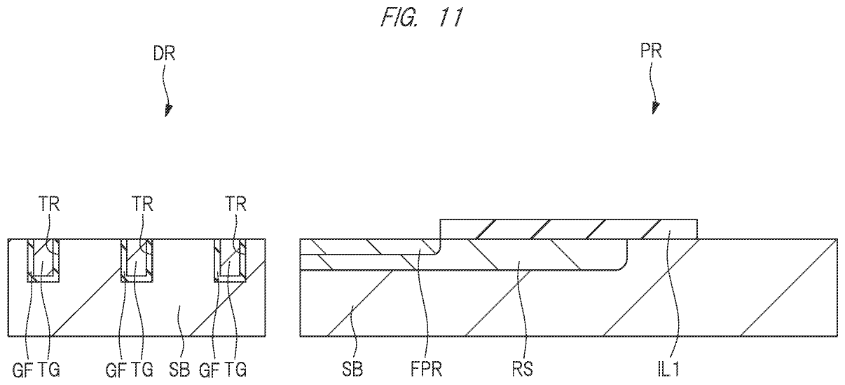

Next, after an insulating film made of a silicon oxide film or the like is formed on the main surface of the semiconductor substrate SB, the insulating film is patterned using the photolithography technique and the etching technique, thereby forming a pattern of the insulating film IL1 on the main surface of the semiconductor substrate SB in the peripheral region PR as shown in FIG. 10.

Next, ion implantation using a photoresist pattern as a mask is performed on the main surface side of the semiconductor substrate SB in the peripheral region PR, thereby forming the p⁻-type RESURF region RS.

Then, ion implantation using a photoresist pattern and the insulating film IL1 as a mask is performed on the main surface side of the semiconductor substrate SB in the peripheral region PR, thereby forming the p-type semiconductor region FPR. The p-type semiconductor region FPR is formed in a self-aligned manner with respect to the inner peripheral edge of the insulating film IL1.

Next, as shown in FIG. 11, after forming the trenches TR in the semiconductor substrate SB in the element region DR by etching, the gate insulating film GF is formed by the thermal oxidation or the like on the inner surfaces (side surfaces and bottom surfaces) of the trenches TR. Thereafter, on the main surface of the semiconductor substrate SB, a conductor film (for example, a polycrystalline silicon film) for forming the trench gate electrode TG is formed by the CVD (Chemical Vapor Deposition) method or the like so as to fill the inside of the trenches TR, and then the conductor film is etched back. In this way, the trench gate electrodes TG each composed of the conductor film left in the trench TR via the gate insulating film GF are formed.

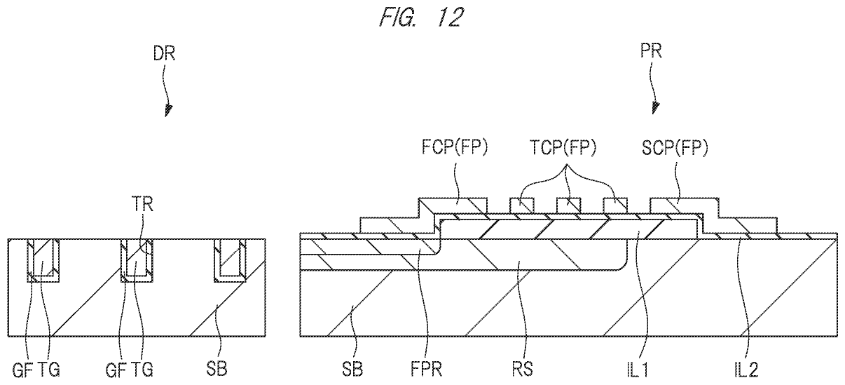

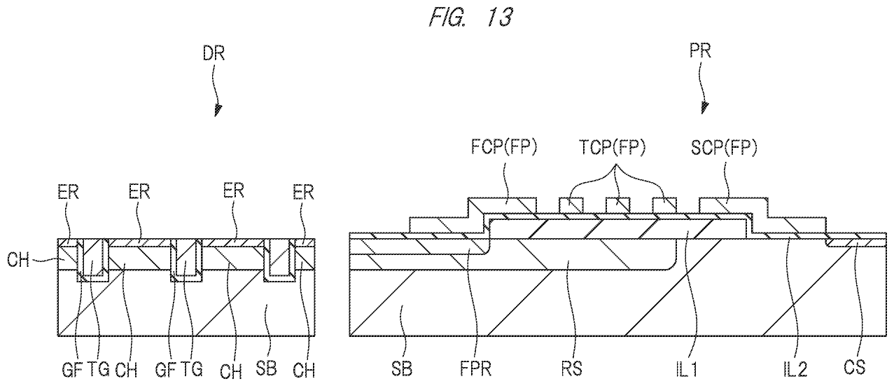

Next, as shown in FIG. 12, after the insulating film IL2 and the polycrystalline silicon film (polycrystalline silicon film for forming the field plate portion FP) are sequentially formed on the main surface of the semiconductor substrate SB by the CVD method or the like, a p-type or n-type impurity is introduced into the polycrystalline silicon film PC by ion implantation. Thereafter, the polycrystalline silicon film is patterned using the photolithography technique and the etching technique to form the conductor patterns FCP, SCP, and TCP constituting the field plate portion FP. This stage is illustrated in FIG. 12. The conductor patterns FCP, SCP, and TCP constituting the field plate portion FP are formed on the main surface of the semiconductor substrate SB via an insulating film (here, an insulating film composed of the insulating film IL1 and the insulating film IL2).

Next, as shown in FIG. 13, ion implantation of a p-type impurity into the semiconductor substrate SB in the element region DR is performed using a photoresist pattern as a mask, thereby forming the p-type channel formation region CH, and then, ion implantation of an n-type impurity is performed using the same photoresist pattern as a mask, thereby forming the n-type emitter region ER.

Next, ion implantation using a photoresist pattern as a mask is performed on the main surface side of the semiconductor substrate SB in the peripheral region PR, thereby forming the n⁺-type channel stopper region CS.

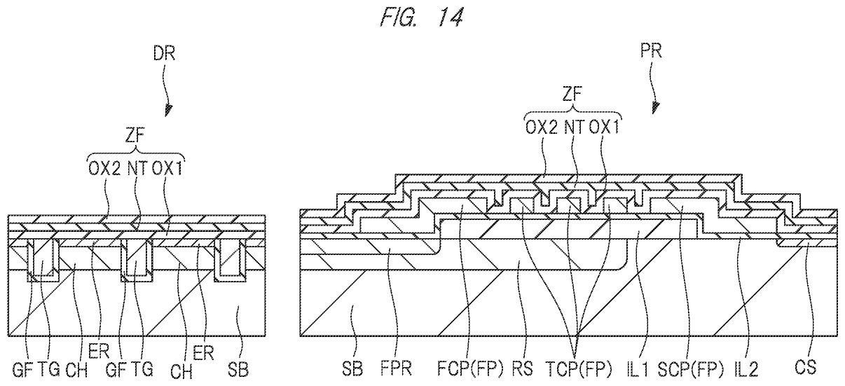

Next, as shown in FIG. 14, the insulating film ZF is formed on the main surface of the semiconductor substrate SB so as to cover the trench gate electrodes TG, the field plate portion FP (conductor patterns FCP, SCP, and TCP), the insulating films IL2, and the insulating films IL1. As described above, the insulating film ZF is composed of a stacked film of one or more silicon nitride films and one or more silicon oxide films. The silicon nitride film and the silicon oxide film that constitute the insulating film ZF can be formed by the CVD method or the like.

In the case of FIG. 14, the insulating film ZF is composed of a stacked film of the silicon oxide film OX1, the silicon nitride film NT on the silicon oxide film OX1, and the silicon oxide film OX2 on the silicon nitride film NT. In this case, the step of forming the insulating film ZF includes a step of forming the silicon oxide film OX1, a step of forming the silicon nitride film NT on the silicon oxide film OX1, and a step of forming the silicon oxide film OX2 on the silicon nitride film NT.

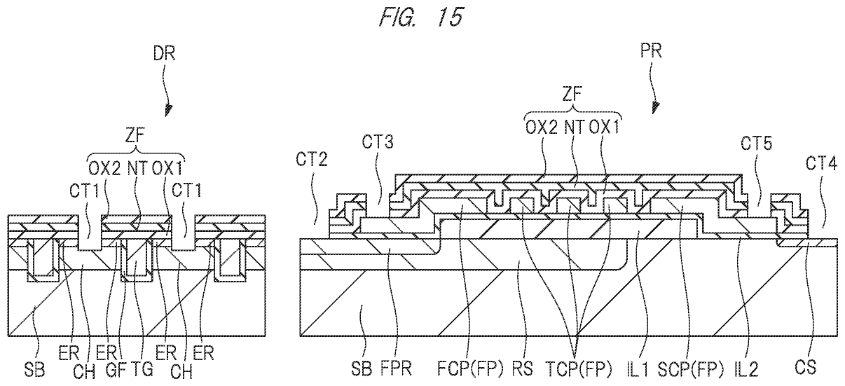

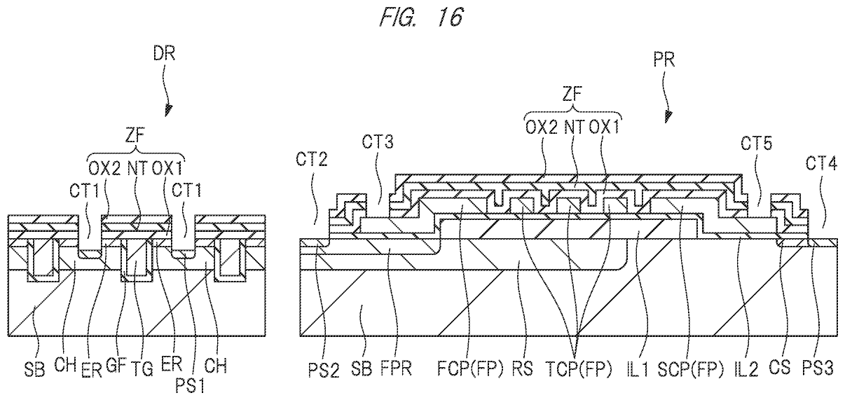

Next, as shown in FIG. 15, the contact holes CT1 are formed in the insulating film ZF by using the photolithography technique and the etching technique. By etching the semiconductor substrate SB at the bottom of the contact hole CT1, the contact hole CT1 is formed to reach the channel formation region CH through the insulating film ZF and the emitter region ER. Further, the contact holes CT2, CT3, CT4, and CT5 are formed in the insulating film ZF by using the photolithography technique and the etching technique.

Next, as shown in FIG. 16, the p⁺-type semiconductor regions PS1, PS2, and PS3 are formed by ion implantation. The p⁺-type semiconductor region PS1 is formed in the channel formation region CH exposed at the bottom of the contact hole CT1, the p⁺-type semiconductor region PS2 is formed in the semiconductor substrate SB exposed at the bottom of the contact hole CT3, and the p⁺-type semiconductor region PS3 is formed in semiconductor substrate SB exposed at the bottom of contact hole CT5. At this time, a p⁺-type semiconductor region (not shown) may be formed in the upper portion of the conductor pattern FCP exposed at the bottom of the contact hole CT3 and in the upper portion of the conductor pattern SCP exposed at the bottom of the contact hole CT5.

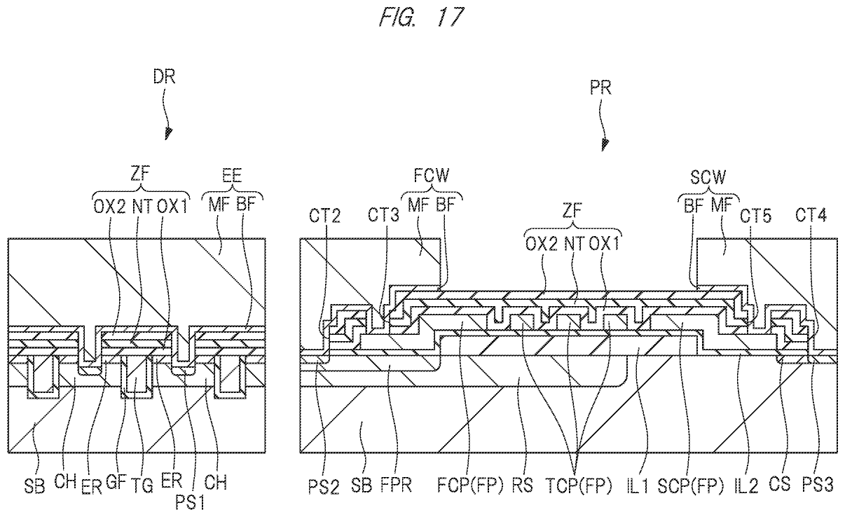

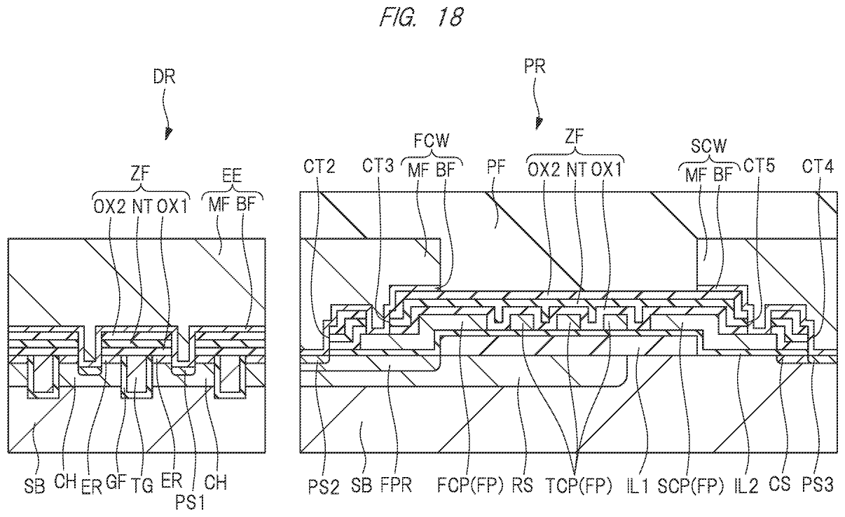

Next, as shown in FIG. 17, on the insulating film ZF including the inner surfaces (side surfaces and bottom surfaces) of the contact holes CT1, CT2, CT3, CT4, and CT5, the barrier conductor film BF is formed using the sputtering method or the like, and then, the main conductor film MF is formed on the barrier conductor film BF by the sputtering method or the like so as to fill the contact holes CT1, CT2, CT3, CT4, and CT5. Thereafter, the main conductor films of the barrier conductor film BF and the main conductor film MF are patterned using the photolithography technique and the etching technique, thereby forming the emitter electrode EE, the gate electrode wiring GEW, the inner circumferential wiring FCW, and the outer circumferential wiring SCW. This stage is illustrated in FIG. 17.

Next, as shown in FIG. 18, the protective film PF made of polyimide resin or the like is formed on the insulating film ZF so as to cover the emitter electrode EE, the gate electrode wiring GEW, the inner circumferential wiring FCW, and the outer circumferential wiring SCW. Then, the opening for emitter pad and the opening for gate pad are formed in the protective film PF. The emitter pad is formed of a part of the emitter electrode EE exposed from the opening for emitter pad in the protective film PF, and the gate pad is formed of the gate electrode portion GE of the gate electrode wiring GEW exposed from the opening for gate pad in the protective film PF.

Next, the semiconductor substrate SB is thinned by grinding the back side of the semiconductor substrate SB as necessary.

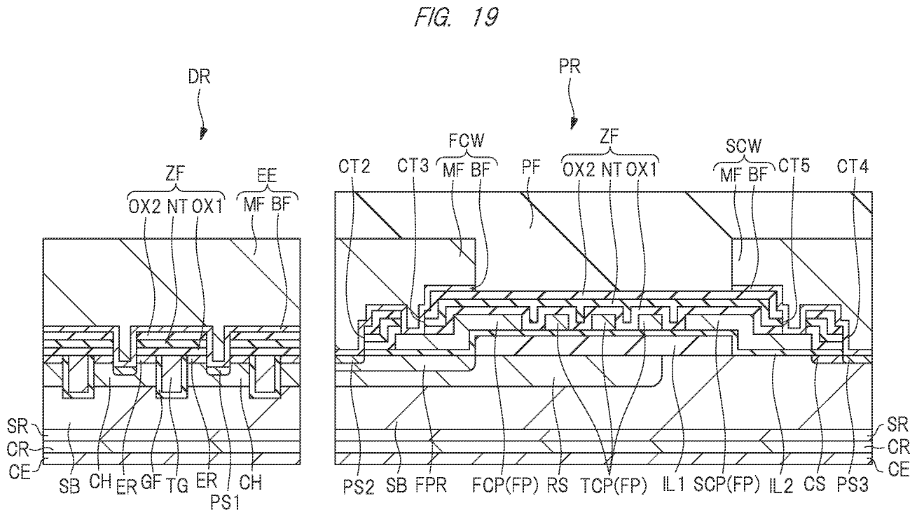

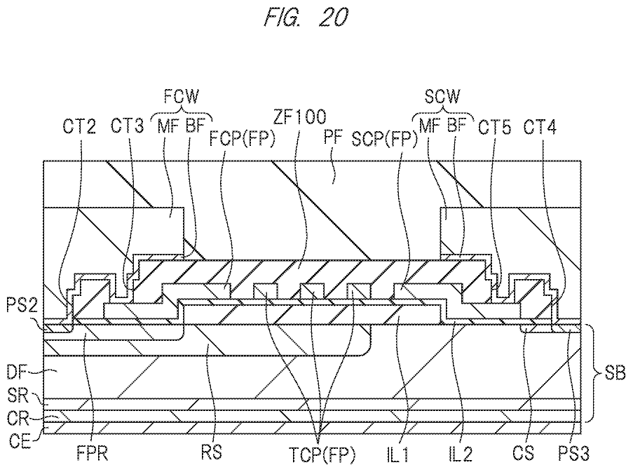

Next, as shown in FIG. 19, the n-type field stop region SR is formed on the back surface side of the semiconductor substrate SB by ion implantation, and then the p-type collector region CR is formed by ion implantation.

Next, the collector electrode CE is formed on the back surface of the semiconductor substrate SB by using the sputtering method or the like. Thereafter, the semiconductor substrate SB is cut into individual pieces by dicing. In this way, the semiconductor device CP as a semiconductor chip is manufactured.

Further, a semiconductor package can be manufactured using the semiconductor device CP thus manufactured. For example, after mounting the semiconductor device CP on a die pad of a lead frame (not shown) and electrically connecting the die pad and the collector electrode CE of the semiconductor device CP, a plurality of leads of the lead frame and the emitter pad (emitter electrode EE) and the gate pad (gate electrode GE) of the semiconductor device CP are electrically connected via conductive connection members (for example, bonding wires). Then, after the semiconductor device CP, the conductive connection members, the die pad, and the leads are sealed with resin, the leads and the die pad are cut and separated from the lead frame. In this way, the semiconductor package can be manufactured.

<Background of Study>

The inventors of this application have studied a semiconductor device having a resistive field plate portion. The resistive field plate portion (corresponding to the field plate portion FP described above) is made of polycrystalline silicon and formed on the main surface of the semiconductor substrate SB via an insulating film.

FIG. 20 is a cross-sectional view showing the principal part of a semiconductor device according to the first studied example studied by the inventors of this application, and corresponds to FIG. 6 above. In the semiconductor device of the first studied example shown in FIG. 20, an insulating film ZF100 corresponding to the insulating film ZF described above is composed of a single silicon oxide film.

As to the semiconductor device having a resistive field plate portion, it is important to improve the moisture resistance. This is because, if moisture enters the semiconductor device CP and reaches the field plate portion FP, the field plate portion FP made of polycrystalline silicon may react with the moisture to be deteriorated. For example, the field plate portion FP has a pattern with a small width (conductor pattern TCP), and there is a risk that the thin pattern reacts with the moisture that has entered, resulting in the breakage of the pattern.

In the semiconductor device according to the first studied example shown in FIG. 20, the insulating film ZF100 covering the field plate portion FP is composed of a single silicon oxide film. A silicon oxide film is a film that has low barrier properties against moisture and easily allows moisture to pass therethrough (film with high moisture permeability). Therefore, the moisture that has passed through the protective film PF is likely to further pass through the insulating film ZF100 and reach the field plate portion FP, so there is concern that the field plate portion FP reacts with the moisture. The reaction of the field plate portion FP with moisture leads to the deterioration in reliability of the semiconductor device. In order to improve the reliability of the semiconductor device having a resistive field plate portion, it is important to prevent the resistive field plate portion made of polycrystalline silicon from reacting with moisture.

<Main Features and Effects>

The field plate portion FP is made of polycrystalline silicon and is formed on the main surface of the semiconductor substrate SB via an insulating film (here, an insulating film composed of the insulating film IL1 and the insulating film IL2), and the insulating film ZF is formed on the insulating film so as to cover the field plate portion FP.

In the present embodiment, the insulating film ZF is composed of a stacked film of one or more silicon nitride films and one or more silicon oxide films. In the case of FIG. 6 to FIG. 8, the insulating film ZF is composed of a stacked film of the silicon oxide film OX1, the silicon nitride film NT on the silicon oxide film OX1, and the silicon oxide film OX2 on the silicon nitride film NT. Compared with a silicon oxide film, a silicon nitride film is a film that has high barrier properties against moisture and does not allow moisture to pass easily (film with low moisture permeability). In the present embodiment, the insulating film ZF covering the field plate portion FP includes the silicon nitride film NT having high barrier properties against moisture, and the silicon nitride film NT included in the insulating film ZF can function as a barrier film against moisture. Therefore, since the insulating film ZF includes the silicon nitride film NT, it is possible to suppress or prevent moisture from passing through the insulating film ZF and reaching the field plate portion FP. As a result, it is possible to suppress or prevent the field plate portion FP made of polycrystalline silicon from reacting with moisture, and the reliability of the semiconductor device having the resistive field plate portion can be improved.

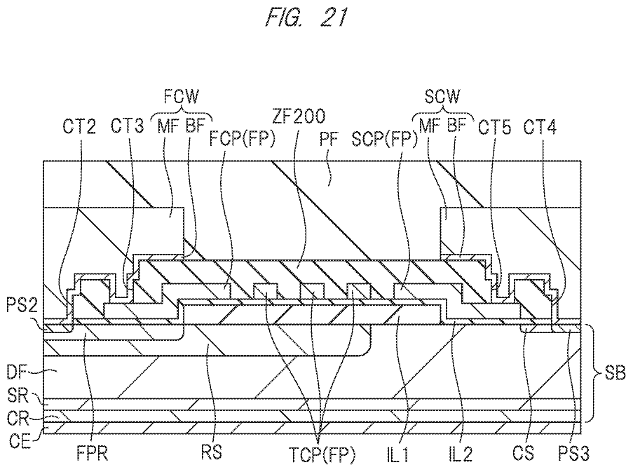

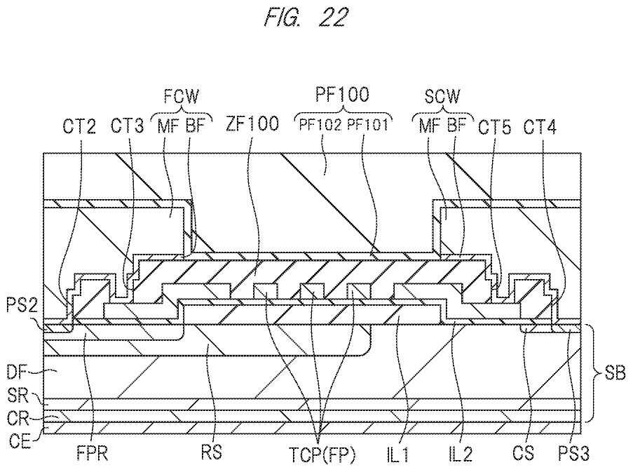

FIG. 21 is a cross-sectional view showing the principal part of a semiconductor device according to the second studied example studied by the inventors of this application, and corresponds to FIG. 6 above. In the semiconductor device of the second studied example shown in FIG. 21, an insulating film ZF200 corresponding to the insulating film ZF described above is composed of a single silicon nitride film.

In the case of the second studied example shown in FIG. 21, since the insulating film ZF200 covering the field plate portion FP is composed of a single silicon nitride film, it is possible to suppress or prevent moisture from passing through the insulating film ZF200 and reaching the field plate portion FP. As a result, it is possible to suppress or prevent the field plate portion FP made of polycrystalline silicon from reacting with moisture.

However, in the case of the second studied example shown in FIG. 21, since the insulating film ZF200 covering the field plate portion FP is composed of a single silicon nitride film, the following problems are caused.

Namely, the silicon nitride film formed on the main surface of the semiconductor substrate is more likely to generate stress to the semiconductor substrate as compared with the silicon oxide film formed on the main surface of the semiconductor substrate. In addition, the silicon nitride film formed on the main surface of the semiconductor substrate generates greater stress to the semiconductor substrate as the thickness thereof increases. Therefore, in the case of the second studied example shown in FIG. 21, since the insulating film ZF200 covering the field plate portion FP is composed of a single silicon nitride film, the insulating film ZF200 made of silicon nitride is more likely to generate stress to the semiconductor substrate SB. If a large stress is applied to a semiconductor substrate during the manufacture of semiconductor device, it causes warping of the semiconductor substrate, which makes it difficult to manage the manufacturing process of the semiconductor device. In addition, if a large stress is applied to the semiconductor substrate of the manufactured semiconductor device, it may adversely affect the electrical characteristics of the semiconductor device. This is not desirable because it causes variations in the electrical characteristics of the semiconductor device. Therefore, in the case of the second studied example shown in FIG. 21, it is conceivable to reduce the thickness of the insulating film ZF200 in order to suppress the stress generated by the insulating film ZF200 covering the field plate portion FP to the semiconductor substrate SB. However, if the insulating film ZF200 is made thin, the function of protecting the field plate portion FP by the insulating film ZF200 covering the field plate portion FP is degraded. In addition, since the insulating film ZF200 serves also as an interlayer insulating film, the function as an interlayer insulating film is also degraded if the insulating film ZF200 is made thin. Therefore, the insulating film ZF200 needs to be thickened to some extent, but if the insulating film ZF200 is thickened, there is concern that stress is generated to the semiconductor substrate SB due to the insulating film ZF200 as described above.

In contrast, in the present embodiment, the insulating film ZF is composed of a stacked film of one or more silicon nitride films and one or more silicon oxide films instead of a single silicon nitride film. Therefore, even if the thickness of the silicon nitride film NT included in the insulating film ZF is not increased, the thickness of the insulating film ZF can be ensured because the insulating film ZF includes one or more silicon oxide films (here, the silicon oxide films OX1 and OX2). Therefore, while suppressing the thickness of the silicon nitride film NT included in the insulating film ZF, the thickness of the insulating film ZF can be ensured, and the function of protecting the field plate portion FP by the insulating film ZF covering the field plate portion FP can be ensured. Moreover, the function of the insulating film ZF as an interlayer insulating film can also be ensured.

In addition, the silicon oxide film formed on the main surface of the semiconductor substrate is less likely to generate stress to the semiconductor substrate as compared with the silicon nitride film formed on the main surface of the semiconductor substrate. Therefore, in the present embodiment, even if the insulating film ZF includes one or more silicon oxide films (here, the silicon oxide films OX1 and OX2), the stress generated to the semiconductor substrate SB can be suppressed. In the present embodiment, since the insulating film ZF includes one or more silicon oxide films (here, the silicon oxide films OX1 and OX2), the thickness of the silicon nitride film NT included in the insulating film ZF can be suppressed, so that the stress generated to the semiconductor substrate SB due to the silicon film NT can be suppressed or prevented. In this way, warping of the semiconductor substrate due to the stress generated to the semiconductor substrate during the manufacture of semiconductor device can be suppressed or prevented, so that management of the manufacturing process of the semiconductor device can be facilitated. In addition, in the manufactured semiconductor device, it is possible to suppress or prevent the stress generated to the semiconductor substrate from affecting the electrical characteristics of the semiconductor device. Therefore, the reliability of the semiconductor device can be improved.

FIG. 22 is a cross-sectional view showing the principal part of a semiconductor device according to the third studied example studied by the inventors of this application, and corresponds to FIG. 6 above. In the semiconductor device according to the third studied example shown in FIG. 22, the insulating film ZF100 corresponding to the insulating film ZF described above is composed of a single silicon oxide film as in the first studied example described above. Also, in the semiconductor device according to the third studied example shown in FIG. 22, a protective film PF100 corresponding to the protective film PF described above is composed of a stacked film of a silicon nitride film PF101 and a resin film PF102 on the silicon nitride film PF101.

In the case of the third studied example shown in FIG. 22, the protective film PF100 includes the silicon nitride film PF101, and the silicon nitride film PF101 can function as a barrier film against moisture. Therefore, in the case of the third studied example shown in FIG. 22, it is possible to suppress or prevent moisture from passing through the silicon nitride film PF101, and it is thus possible to suppress or prevent moisture from reaching the field plate portion FP through the silicon nitride film PF101 and the insulating film ZF100. Accordingly, it is possible to suppress or prevent the from reacting with moisture.

However, in the case of the third studied example shown in FIG. 22, cracks may occur in the silicon nitride film PF101. The reason will be described below.

Namely, in the case of the third studied example shown in FIG. 22, the protective film PF100 including the silicon nitride film PF101 is formed so as to cover the emitter electrode EE, the gate electrode wiring GEW, the inner circumferential wiring FCW, and the outer circumferential wiring SCW, and the emitter electrode EE, the gate electrode wiring GEW, the inner circumferential wiring FCW, and the outer circumferential wiring SCW have large thickness. Therefore, in the silicon nitride film PF101 covering the thick electrodes (the emitter electrode EE, the gate electrode wiring GEW, the inner circumferential wiring FCW, and the outer circumferential wiring SCW), a large stepped portion is formed, and cracks are likely to occur due to stress concentrated on the stepped portion. When cracks occur in the silicon nitride film PF101, the function of preventing the intrusion of moisture by the silicon nitride film PF101 is degraded, so that moisture reaches the field plate portion FP through the silicon nitride film PF101 and the insulating film ZF100 and the phenomenon that the field plate portion FP made of polycrystalline silicon reacts with moisture is likely to occur. In order to prevent cracks in the silicon nitride film PF101, it is necessary to reduce the thicknesses of the emitter electrode EE, the gate electrode wiring GEW, the inner circumferential wiring FCW, and the outer circumferential wiring SCW, but the thickness reduction is not desirable because it may degrade the performance of the semiconductor device. This is because the emitter electrode EE, the gate electrode wiring GEW, the inner circumferential wiring FCW, and the outer circumferential wiring SCW desirably have low resistance and they must be thickened to some extent for that purpose. In addition, the emitter electrode EE, the gate electrode wiring GEW, the inner circumferential wiring FCW, and the outer circumferential wiring SCW are made of a metal material instead of polycrystalline silicon in order to reduce resistance. Further, when the thicknesses of the emitter electrode EE, the gate electrode wiring GEW, the inner circumferential wiring FCW, and the outer circumferential wiring SCW are reduced, there is concern about the damage (for example, damage to the structure below the pads) due to pressure and ultrasonic vibration applied to the emitter pads and gate pads in the wire bonding process when manufacturing a semiconductor package using a semiconductor device (semiconductor chip).

In contrast, in the present embodiment, the emitter electrode EE, the gate electrode wiring GEW, the inner circumferential wiring FCW, and the outer circumferential wiring SCW are formed on the insulating film ZF. Therefore, the insulating film ZF is located in a layer lower than the emitter electrode EE, the gate electrode wiring GEW, the inner circumferential wiring FCW, and the outer circumferential wiring SCW, and thus the silicon nitride film NT included in the insulating film ZF is located in a layer lower than the emitter electrode EE, the gate electrode wiring GEW, the inner circumferential wiring FCW, and the outer circumferential wiring SCW. Namely, the silicon nitride film NT included in the insulating film ZF exists below each of the emitter electrode EE, the gate electrode wiring GEW, the inner circumferential wiring FCW, and the outer circumferential wiring SCW, but does not exist above the emitter electrode EE, the gate electrode wiring GEW, the inner circumferential wiring FCW, and the outer circumferential wiring SCW. In other words, the silicon nitride film NT included in the insulating film ZF does not run on the emitter electrode EE, the gate electrode wiring GEW, the inner circumferential wiring FCW, and the outer circumferential wiring SCW.

Therefore, the stepped portion caused by the emitter electrode EE, the gate electrode wiring GEW, the inner circumferential wiring FCW, or the outer circumferential wiring SCW does not occur in the insulating film ZF and the silicon nitride film NT included in the insulating film ZF. Accordingly, even if the thicknesses of the emitter electrode EE, the gate electrode wiring GEW, the inner circumferential wiring FCW, and the outer circumferential wiring SCW are large, there is no influence on the insulating film ZF and the silicon nitride film NT included in the insulating film ZF. Further, the thickness of the field plate portion FP (conductor patterns FCP, TCP, and SCP) is smaller than the thickness of each of the gate electrode wiring GEW, the inner circumferential wiring FCW, and the outer circumferential wiring SCW. This is because the emitter electrode EE, the gate electrode wiring GEW, the inner circumferential wiring FCW, and the outer circumferential wiring SCW need to be made of a metal material for the reduction in resistance and have a certain thickness, but the field plate portion FP needs to be made of polycrystalline silicon instead of a metal material in order to increase the resistance to some extent and does not need to have a large thickness. Accordingly, even if a stepped portion due to the field plate portion FP occurs in the silicon nitride film NT included in the insulating film ZF covering the field plate portion FP, the size of the stepped portion is smaller than that of the stepped portion which occurs in the silicon nitride film PF101 in the third studied example shown in FIG. 22 above. Therefore, the risk of occurrence of cracks in the silicon nitride film NT included in the insulating film ZF covering the field plate portion FP is lower than the risk of occurrence of cracks in the silicon nitride film PF101 in the third studied example shown FIG. 22 above.

Therefore, as compared with the silicon nitride film PF101 of the third studied example shown in FIG. 22 above, cracks are less likely to occur in the silicon nitride film NT included in the insulating film ZF covering the field plate portion FP, and thus the silicon nitride film NT included in the insulating film ZF can appropriately maintain the function of preventing intrusion of moisture. As a result, it is possible to appropriately suppress or prevent moisture from reaching the field plate portion FP through the silicon nitride film NT included in the insulating film ZF, and it is possible to appropriately suppress or prevent the occurrence of the phenomenon that the field plate portion FP made of polycrystalline silicon reacts with moisture. Therefore, it is possible to appropriately improve the reliability of the semiconductor device having the resistive field plate portion.

Further, in the present embodiment, the protective film PF does not include a silicon nitride film. In the case of the third studied example shown in FIG. 22, there is concern that a large stepped portion occurs in the silicon nitride film PF101 included in the protective film PF100 and cracks occur due to the stepped portion because the protective film PF100 includes the silicon nitride film PF101. However, in the present embodiment, such a concern does not arise because the protective film PF does not include a silicon nitride film.

Moreover, the protective film PF is preferably composed of a resin film. A resin film is softer than an inorganic insulating film. By using a resin film as the protective film PF, the handling of the semiconductor device CP becomes easier. However, the resin film is more permeable to moisture than the inorganic insulating film. Therefore, when a resin film is used as the protective film PF, moisture easily passes through the protective film PF. In contrast, in the present embodiment, since the silicon nitride film NT included in the insulating film ZF covering the field plate portion FP can function as a barrier film against moisture, it is possible to suppress or prevent moisture passing through the protective film PF from reaching the field plate part FP through the insulating film ZF. Therefore, even when a resin film is used as the protective film PF, it is possible to appropriately suppress or prevent the from reacting with moisture, and the reliability of the semiconductor device having the resistive field plate portion can be improved appropriately.

<Modification>

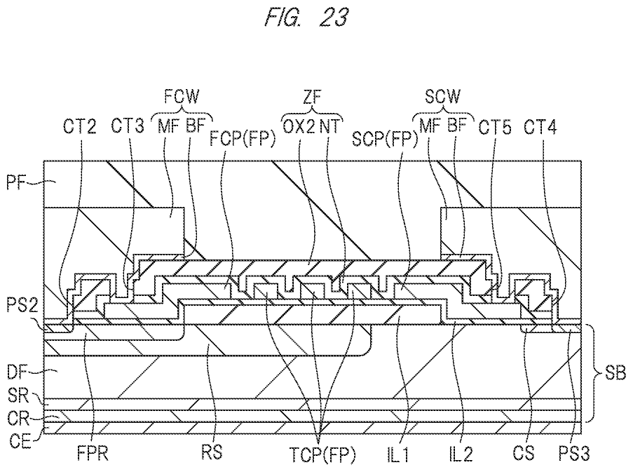

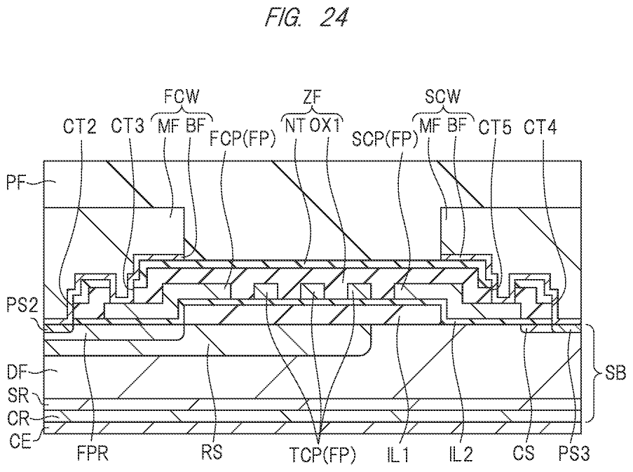

FIG. 23 is a cross-sectional view showing the principal part in the first modification of the semiconductor device CP according to the present embodiment, and FIG. 24 is a cross-sectional view showing the principal part in the second modification of the semiconductor device CP according to the present embodiment. Each of FIG. 23 and FIG. 24 is a cross-sectional view corresponding to FIG. 6 above.

The insulating film ZF composed of a stacked film of one or more silicon nitride films and one or more silicon oxide films is common to the case of FIG. 6, the case of FIG. 23 (first modification), and the case of FIG. 24 (second modification). However, the specific configuration of the stacked film constituting the insulating film ZF is different among the case of FIG. 6, the case of FIG. 23 (first modification), and the case of FIG. 24 (second modification).

Namely, in the case of FIG. 6, the insulating film ZF is composed of a stacked film of the silicon oxide film OX1, the silicon nitride film NT on the silicon oxide film OX1, and the silicon oxide film OX2 on the silicon nitride film NT. Then, the silicon oxide film OX1 in the lowermost layer of the stacked film constituting the insulating film ZF is in contact with the field plate portion FP (conductor patterns FCP, TCP, and SCP), and the silicon oxide film OX2 in the uppermost layer of the stacked film constituting the insulating film ZF is in contact with the emitter electrode EE, the gate electrode wiring GEW, the inner circumferential wiring FCW, and the outer circumferential wiring SCW.

In the case of FIG. 23 (first modification), the insulating film ZF is composed of a stacked film of the silicon nitride film NT and the silicon oxide film OX2 on the silicon nitride film NT. Then, the silicon nitride film NT in the lowermost layer of the stacked film constituting the insulating film ZF is in contact with the field plate portion FP (conductor patterns FCP, TCP, and SCP), and the silicon oxide film OX2 in the uppermost layer of the stacked film constituting the insulating film ZF is in contact with the emitter electrode EE, the gate electrode wiring GEW, the inner circumferential wiring FCW, and the outer circumferential wiring SCW.

In the case of FIG. 24 (second modification), the insulating film ZF is composed of a stacked film of the silicon oxide film OX1 and the silicon nitride film NT on the silicon oxide film OX1. Then, the silicon oxide film OX1 in the lowermost layer of the stacked film constituting the insulating film ZF is in contact with the field plate portion FP (conductor patterns FCP, TCP, and SCP), and the silicon nitride film NT in the uppermost layer of the stacked film constituting the insulating film ZF is in contact with the emitter electrode EE, the gate electrode wiring GEW, the inner circumferential wiring FCW, and the outer circumferential wiring SCW.

In any of the case of FIG. 6, the case of FIG. 23 (first modification), and the case of FIG. 24 (second modification), the insulating film ZF includes the silicon nitride film NT, and it is thus possible to suppress or prevent moisture from reaching the field plate portion FP through the insulating film ZF as described above. As a result, it is possible to suppress or prevent the field plate portion FP made of polycrystalline silicon from reacting with moisture, and the reliability of the semiconductor device having the resistive field plate portion can be improved.

In any of the case of FIG. 6, the case of FIG. 23 (first modification), and the case of FIG. 24 (second modification), the insulating film ZF includes also a silicon oxide film, and it is thus possible to ensure the thickness of the insulating film ZF even if the thickness of the silicon nitride film NT included in the insulating film ZF is not increased. Therefore, while suppressing the thickness of the silicon nitride film NT included in the insulating film ZF, the thickness of the insulating film ZF can be ensured, and the function of protecting the field plate portion FP by the insulating film ZF covering the field plate portion FP can be ensured. Moreover, the function of the insulating film ZF as an interlayer insulating film can also be ensured. In addition, it is possible to suppress or prevent stress generated to the semiconductor substrate SB due to the silicon nitride film NT.

In each of the case of FIG. 6, the case of FIG. 23 (first modification), and the case of FIG. 24 (second modification), the thickness of the insulating film ZF can be, for example, about 400 nm to 2000 nm, and the thickness of the silicon nitride film NT can be, for example, about 10 nm to 300 nm.

Moreover, in each of the case of FIG. 6, the case of FIG. 23 (first modification), and the case of FIG. 24 (second modification), it is preferable that a thickness capable of obtaining a certain degree of barrier function against moisture is ensured as the thickness of the silicon nitride film NT. From this point of view, it is preferable to set the thickness of the silicon nitride film NT to 10 nm or more. Further, since it is desirable to suppress the thickness of the silicon nitride film NT in order to suppress the generation of stress to the semiconductor substrate SB due to the silicon nitride film NT, the thickness of the silicon nitride film NT is preferably less than half the thickness of the insulating film ZF. Namely, it is preferable to allocate the majority (more than half) of the thickness of the insulating film ZF to the silicon oxide film. Therefore, in the case of FIG. 6, it is preferable that the thickness of the silicon nitride film NT is smaller than the total thickness of the silicon oxide film OX1 and the silicon oxide film OX2. Also, in the case of FIG. 23 (first modification), it is preferable that the thickness of the silicon nitride film NT is smaller than the thickness of the silicon oxide film OX2. Further, in the case of FIG. 24 (second modification), it is preferable that the thickness of the silicon nitride film NT is smaller than the thickness of the silicon oxide film OX1.

By the way, a silicon nitride film is an insulating film having a charge accumulation function. Therefore, in the case of FIG. 23 (first modification), there is following concern because the silicon nitride film NT is in contact with the field plate portion FP. That is, as compared with a silicon oxide film, a silicon nitride film has more charge traps in the film, and charges are more likely to be accumulated in the film. For this reason, the silicon nitride film accumulates charges in the film during film formation, and the charge accumulation state is likely to be maintained even after the semiconductor device is manufactured. Therefore, when the silicon nitride film NT is in contact with the field plate portion FP, the electric charges accumulated in the silicon nitride film NT affect the electrical characteristics of the field plate portion FP, and the electrical characteristics of the field plate portion FP may be fluctuated.

On the other hand, in the case of FIG. 6 and the case of FIG. 24 (second modification), the silicon nitride film NT included in the insulating film ZF is not in contact with the field plate portion FP. Namely, the silicon oxide film OX1 is interposed between the silicon nitride film NT and the field plate portion FP. Therefore, even if charges are accumulated in the silicon nitride film NT, the silicon oxide film OX1 is interposed between the silicon nitride film NT and the field plate portion FP, and it is thus possible to suppress or prevent the charges accumulated in the silicon nitride film NT from affecting the electrical characteristics of the field plate portion FP. Therefore, it is possible to suppress or prevent the electrical characteristics of the field plate portion FP from being fluctuated due to the electric charges accumulated in the silicon nitride film NT.

Further, in the case of FIG. 6, the silicon nitride film NT is not in contact with also the emitter electrode EE, the gate electrode wiring GEW, the inner circumferential wiring FCW, and the outer circumferential wiring SCW, and it is thus possible to prevent charges from moving from the emitter electrode EE, the gate electrode wiring GEW, the inner circumferential wiring FCW, and the outer circumferential wiring SCW and being accumulated in the silicon nitride film NT. Therefore, the case of FIG. 6 is the best for preventing the electrical characteristics of the field plate portion FP from being fluctuated due to the charge accumulated in the silicon nitride film NT.

On the other hand, steps of forming the three insulating films are necessary for forming the insulating film ZF in the case of FIG. 6, and steps of forming the two insulating films are necessary for forming the insulating film ZF in the case of FIG. 23 (first modification) and the case of FIG. 24 (second modification). Therefore, the number of manufacturing steps of the semiconductor device can be reduced in the case of FIG. 23 (first modification) and the case of FIG. 24 (second modification) as compared with the case of FIG. 6.

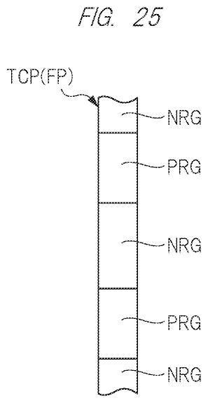

FIG. 25 is a cross-sectional view showing the principal part in the third modification of the semiconductor device CP according to the present embodiment, and the conductor pattern TCP of the field plate portion FP is illustrated.

In the case of FIG. 1 to FIG. 8, the field plate portion FP (conductor patterns FCP, TCP, and SCP) is entirely the p-type semiconductor region or the n-type semiconductor region.

On the other hand, in the case of the third modification shown in FIG. 25, the conductor pattern TCP of the field plate portion FP has a structure in which a plurality of p-type semiconductor regions PRG and n-type semiconductor regions NRG are alternately arranged along the extending direction of the conductor pattern TCP (direction in which current flows). A PN junction is formed between the p-type semiconductor region PRG and the n-type semiconductor region NRG. The conductor pattern FCP of the field plate portion FP is entirely the p-type semiconductor region or the n-type semiconductor region, and the conductor pattern SCP of the field plate portion FP is entirely the p-type semiconductor region or the n-type semiconductor region.

In the case of the third modification shown in FIG. 25, when the current flows through the conductor pattern TCP of the field plate portion FP, the current alternately passes through the p-type semiconductor regions PRG and the n-type semiconductor regions NRG, and thus the current passes through a plurality of PN junctions. Therefore, as compared with the case where the entire field plate portion FP (conductor patterns FCP, TCP, and SCP) is the p-type semiconductor region or the case where the entire field plate portion FP (conductor patterns FCP, TCP, and SCP) is the n-type semiconductor region, the current flowing between the collector and the emitter through the field plate portion FP can be reduced in the case of the third modification shown in FIG. 25. Since the leakage current of the semiconductor element (for example, IGBT) formed in the semiconductor device CP can be suppressed when the third modification shown in FIG. 25 is applied, the third modification is suitable for the semiconductor device for which the low leakage current is required.

In the foregoing, the invention made by the inventors of this application has been specifically described based on the embodiment, but the present invention is not limited to the embodiment described above and can be modified in various ways within the scope not departing from the gist thereof.

What is claimed is:

1. A semiconductor device comprising:
a semiconductor substrate having a main surface and a back surface located on opposite sides to each other;
a field plate portion formed on the main surface of the semiconductor substrate via a first insulating film;
a second insulating film formed on the main surface of the semiconductor substrate so as to cover the first insulating film and the field plate portion;
a first metal pattern and a second metal pattern formed on the second insulating film; and
an insulating protective film formed on the second insulating film so as to cover the first metal pattern and the second metal pattern,
wherein each of the first metal pattern and the second metal pattern is electrically connected to the field plate portion,
wherein each of the first metal pattern and the second metal pattern is thicker than the field plate portion,
wherein the field plate portion is made of polycrystalline silicon, and
wherein the second insulating film is composed of a stacked film of one or more silicon nitride films and one or more silicon oxide films.

2. The semiconductor device according to claim 1,
wherein the second insulating film is composed of a stacked film of a first silicon oxide film, a first silicon nitride film on the first silicon oxide film, and a second silicon oxide film on the first silicon nitride film.

3. The semiconductor device according to claim 2,
wherein the first silicon oxide film is in contact with the field plate portion.

4. The semiconductor device according to claim 1,
wherein the second insulating film is composed of a stacked film of a first silicon oxide film and a first silicon nitride film on the first silicon oxide film.

5. The semiconductor device according to claim 4,
wherein the first silicon oxide film is in contact with the field plate portion.

6. The semiconductor device according to claim 1,
wherein the second insulating film is composed of a stacked film of a first silicon nitride film and a first silicon oxide film on the first silicon nitride film.

7. The semiconductor device according to claim 6,
wherein the first silicon nitride film is in contact with the field plate portion.

8. The semiconductor device according to claim 1,
wherein the protective film is in contact with the first metal pattern and the second metal pattern, and
wherein the protective film does not include a silicon nitride film.

9. The semiconductor device according to claim 8,
wherein the protective film is a film in an uppermost layer.

10. The semiconductor device according to claim 1,
wherein the protective film is composed of a resin film.

11. The semiconductor device according to claim 1,
wherein an element region in which a semiconductor element is formed is arranged in a central part of the main surface of the semiconductor substrate,
wherein the first metal pattern is arranged so as to surround the element region in plan view and is electrically connected to a first portion of the semiconductor substrate exposed from the second insulating film,
wherein the second metal pattern is arranged so as to surround the first metal pattern in plan view and is electrically connected to a second portion of the semiconductor substrate exposed from the second insulating film,
wherein the field plate portion integrally includes a first conductor pattern arranged so as to surround the element region in plan view, a second conductor pattern arranged so as to surround the first conductor pattern in plan view, and a third conductor pattern arranged between the first conductor pattern and the second conductor pattern in plan view and connecting the first conductor pattern and the second conductor pattern,
wherein the first metal pattern is electrically connected to the first conductor pattern of the field plate portion, and
wherein the second metal pattern is electrically connected to the second conductor pattern of the field plate portion.

12. The semiconductor device according to claim 11,
wherein a first electrode for the semiconductor element is formed on the second insulating film on the element region,
wherein a second electrode for the semiconductor element is formed on the back surface of the semiconductor substrate, and
wherein the protective film covers a part of the first electrode.

13. The semiconductor device according to claim 12,
wherein the first metal pattern is electrically connected to the first electrode, and
wherein the second metal pattern is electrically connected to the second electrode through the semiconductor substrate.

14. The semiconductor device according to claim 11,
wherein a plurality of p-type semiconductor regions and n-type semiconductor regions are alternately arranged in the third conductor pattern along an extending direction of the third conductor pattern.

15. A manufacturing method of a semiconductor device comprising:
(a) a step of preparing a semiconductor substrate having a main surface and a back surface located on opposite sides to each other;
(b) a step of forming a semiconductor element in an element region of the semiconductor substrate;
(c) a step of forming a field plate portion on the main surface of the semiconductor substrate via a first insulating film;
(d) a step of forming a second insulating film on the main surface of the semiconductor substrate so as to cover the first insulating film and the field plate portion;
(e) a step of forming a first metal pattern and a second metal pattern on the second insulating film; and
(f) a step of forming an insulating protective film on the second insulating film so as to cover the first metal pattern and the second metal pattern,
wherein each of the first metal pattern and the second metal pattern is electrically connected to the field plate portion,
wherein the field plate portion is made of polycrystalline silicon, and
wherein the second insulating film is composed of a stacked film of one or more silicon nitride films and one or more silicon oxide films.

16. The manufacturing method of the semiconductor device according to claim 15,
wherein, in the step (e), a first electrode for the semiconductor element is formed on the second insulating film on the element region,
the method further comprising: after the step (f),
(g) a step of forming a second electrode for the semiconductor element on the back surface of the semiconductor substrate,
wherein the first metal pattern is electrically connected to the first electrode, and
wherein the second metal pattern is electrically connected to the second electrode through the semiconductor substrate.

17. The manufacturing method of the semiconductor device according to claim 15,
wherein the second insulating film is composed of a stacked film of a first silicon oxide film in contact with the field plate portion, a first silicon nitride film on the first silicon oxide film, and a second silicon oxide film on the first silicon nitride film.

18. The manufacturing method of the semiconductor device according to claim 15,
wherein the second insulating film is composed of a stacked film of a first silicon oxide film in contact with the field plate portion and a first silicon nitride film on the first silicon oxide film.

19. The manufacturing method of the semiconductor device according to claim 15,
wherein the second insulating film is composed of a stacked film of a first silicon nitride film in contact with the field plate portion and a first silicon oxide film on the first silicon nitride film.

20. The manufacturing method of the semiconductor device according to claim 15,
wherein the protective film is in contact with the first metal pattern and the second metal pattern and does not include a silicon nitride film.
